(19) United States
(12) Patent Application Publication
(10) Pub. No.: US 2025/0253183 A1
(43) Pub. Date: Aug. 7, 2025

(54) PRESSURE-SENSITIVE ADHESIVE TAPE FOR SEMICONDUCTOR WAFER PROCESSING

(71) Applicant: NITTO DENKO CORPORATION, Osaka (JP)

(72) Inventors: Akihiro FUKUI, Ibaraki-shi (JP); Keita MIKI, Ibaraki-shi (JP); Mariko TESHIBA, Ibaraki-shi (JP); Sho KONDO, Ibaraki-shi (JP)

(21) Appl. No.: 19/042,285

(22) Filed: Jan. 31, 2025

(30) Foreign Application Priority Data
Feb. 2, 2024 (JP) 2024-015268

(51) Int. Cl. H01L 21/683

(52) U.S. Cl. CPC H01L 21/6836; H01L 2221/6834

(57) ABSTRACT

Provided is a pressure-sensitive adhesive tape for semiconductor wafer processing that is excellent in unevenness-embedding property, and is suppressed from creating adhesive residue on the surface of a semiconductor wafer. The pressure-sensitive adhesive tape for semiconductor wafer processing includes: a base material; and a pressure-sensitive adhesive layer formed of an active energy ray-curable pressure-sensitive adhesive. A surface free energy X (mN/m) of the pressure-sensitive adhesive layer, and a quotient Y (I_{A}/T_{A}) between a tack value T_{A} (gf) and an integrated value I_{A} (gf·sec) of the pressure-sensitive adhesive layer measured by a probe tack method satisfy a relationship of Y>0.01X-0.21.

This application claims priority under 35 U.S.C. Section 119 to Japanese Patent Application No. 2024-015268 filed on Feb. 2, 2024, which is herein incorporated by reference.

### BACKGROUND OF THE INVENTION

### 1. Field of the Invention

The present invention relates to a pressure-sensitive adhesive tape for semiconductor wafer processing.

### 2. Description of the Related Art

A semiconductor wafer is used for various usages, such as a personal computer, a smartphone, and an automobile. In the processing step of the semiconductor wafer, a pressure-sensitive adhesive tape is used for protecting a surface thereof at the time of processing. In recent years, miniaturization and high functionalization of a large-scale integration (LSI) have been proceeding, and a surface structure of the wafer has become complicated.A specific example thereof is the complication of the three-dimensional structure of the wafer surface by a solder bump or the like. Accordingly, the pressure-sensitive adhesive tape to be used in the semiconductor wafer processing step is required to have such a property as to embed the unevenness of the wafer surface and a strong pressure-sensitive adhesive property.

In recent years, along with downsizing and thinning of products, thinning of the semiconductor wafer has been advanced. In the wafer processed into a thin shape, when an adhesive strength of the pressure-sensitive adhesive tape is too high, the wafer may break at the time of peeling of the pressure-sensitive adhesive tape. In view of this, in order to prevent an adhesive residue on an adherend and the breakage of the wafer at the time of peeling, a pressure-sensitive adhesive tape using a UV-curable pressure-sensitive adhesive has been proposed (for example, Japanese Patent Application Laid-open No. 2020-017758 and Japanese Patent Application Laid-open No. 2013-213075). In addition, as a pressure-sensitive adhesive tape suitable for processing of a semiconductor wafer having an uneven structure such as a bump, a pressure-sensitive adhesive tape having an excellent unevenness-embedding property has been proposed (for example, Japanese Patent Application Laid-open No. 2022-121480).

### SUMMARY OF THE INVENTION

A pressure-sensitive adhesive tape having an excellent unevenness-embedding property may have a problem of leaving an adhesive residue on the surface of a semiconductor wafer after the peeling of the pressure-sensitive adhesive tape. The present invention has been made to solve the above-mentioned problem of the related art, and provides a pressure-sensitive adhesive tape for semiconductor wafer processing that has an excellent unevenness-embedding property, and is suppressed from creating adhesive residue on the surface of a semiconductor wafer.

Aspect 1: According to at least one embodiment of the present invention, there is provided a pressure-sensitive adhesive tape for semiconductor wafer processing, including: a base material; and a pressure-sensitive adhesive layer formed of an active energy ray-curable pressure-sensitive adhesive.A surface free energy X (mN/m) of the pressure-sensitive adhesive layer, and a quotient Y (I_{A}/T_{A}) between a tack value T_{A} (gf) and an integrated value I_{A} (gf·sec) of the pressure-sensitive adhesive layer measured by a probe tack method satisfy a relationship of:

$$Y > 0.01 X - 0.21 .$$

Aspect 2: In the pressure-sensitive adhesive tape for semiconductor wafer processing according to the above-mentioned aspect 1, the active energy ray-curable pressure-sensitive adhesive may contain a (meth) acrylic polymer, and the (meth) acrylic polymer may be a polymer obtained by polymerization of a monomer composition containing 60 mol % or more of a (meth) acrylic monomer having a side chain having 8 or more carbon atoms.

Aspect 3: In the pressure-sensitive adhesive tape for semiconductor wafer processing according to the above-mentioned aspect 2, the monomer composition may contain 39 mol % or less of at least one kind selected from the group consisting of: a monomer having a side chain having 2 or less carbon atoms; and a high-polarity monomer.

Aspect 4: In the pressure-sensitive adhesive tape for semiconductor wafer processing according to the above-mentioned aspect 3, the high-polarity monomer may be a hydroxy group-containing monomer having a side chain having 4 or less carbon atoms.

Aspect 5: In the pressure-sensitive adhesive tape for semiconductor wafer processing according to the above-mentioned aspect 4, the monomer composition may contain 10 mol % to 39 mol % of the hydroxy group-containing monomer having a side chain having 4 or less carbon atoms.

Aspect 6: The pressure-sensitive adhesive tape for semiconductor wafer processing according to any one of the above-mentioned aspects 1 to 5 may further include an intermediate layer. Aspect 7: The pressure-sensitive adhesive tape for semiconductor wafer processing according to any one of the above-mentioned aspects 1 to 6 may be a backgrinding tape.

### BRIEF DESCRIPTION OF THE DRAWINGS

FIG. 1 is a schematic sectional view of a pressure-sensitive adhesive tape for semiconductor wafer processing according to at least one embodiment of the present invention.

FIG. 2 is a schematic sectional view of a pressure-sensitive adhesive tape for semiconductor wafer processing according to at least one embodiment of the present invention.

### DESCRIPTION OF THE EMBODIMENTS

A. Outline of Pressure-sensitive Adhesive Tape for Semiconductor Wafer Processing

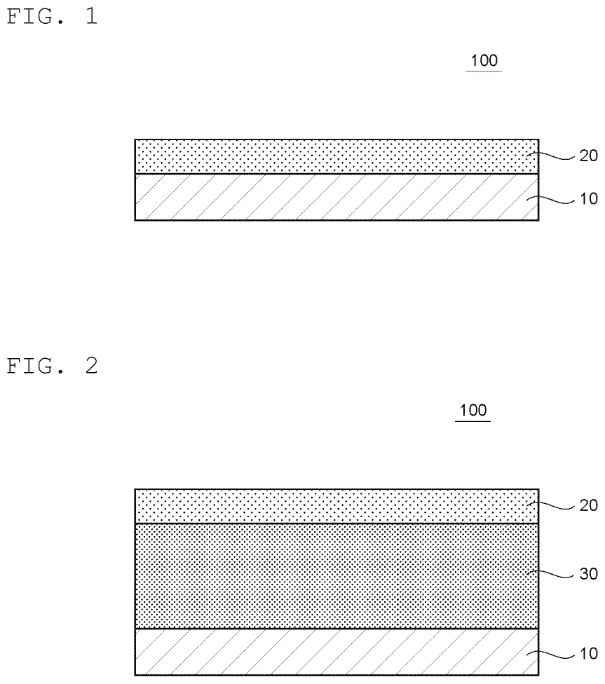

A pressure-sensitive adhesive tape for semiconductor wafer processing according to at least one embodiment of the present invention includes a base material and a pressure-sensitive adhesive layer formed of an active energy ray-curable pressure-sensitive adhesive. FIG. 1 is a schematic sectional view of a pressure-sensitive adhesive tape for semiconductor wafer processing according to at least one embodiment of the present invention. In the illustrated example, a pressure-sensitive adhesive tape 100 for semiconductor wafer processing includes a base material 10 and a pressure-sensitive adhesive layer 20. The pressure-sensitive adhesive for tape semiconductor wafer processing according to at least one embodiment of the present invention preferably further includes an intermediate layer. FIG. 2 is a schematic sectional view of a pressure-sensitive adhesive tape for semiconductor wafer processing according to at least one embodiment of the present t invention. The pressure-sensitive adhesive tape 100 for semiconductor wafer processing in the at least one embodiment includes the base material 10, an intermediate layer 30, and the pressure-sensitive adhesive layer 20 in the stated order. In practical use, in the pressure-sensitive adhesive tape for semiconductor wafer processing according to at least one embodiment of the present invention, a release liner may be peelably temporarily bonded to the pressure-sensitive adhesive layer 20 until use.

In the pressure-sensitive adhesive tape for semiconductor wafer processing according to at least one embodiment of the present invention, a surface free energy X (mN/m) of the pressure-sensitive adhesive layer 20, and a quotient Y (I_{A}/T_{A}) between a tack value T_{A} (gf) and an integrated value I_{A} (gf·sec) of the pressure-sensitive adhesive layer 20 measured by a probe tack method satisfy a relationship of the formula (1). When the relationship of the formula (1) is satisfied, a pressure-sensitive adhesive tape for semiconductor wafer processing that is excellent in unevenness-embedding property, and is suppressed from creating adhesive residue on the surface of a semiconductor wafer can be provided.

$$Y > 0.01 X - 0.21 \qquad ( 1 )$$

Herein, the tack value T_{A} and integrated value I_{A} of the pressure-sensitive adhesive layer 20 measured by the probe tack method as used herein refer to values measured by the probe tack method with a probe tack tester by the following procedure.

A base material surface of the pressure-sensitive adhesive tape and a glass slide are bonded to each other via a double-sided tape so that the pressure-sensitive adhesive tape is fixed to the glass slide. Next, a probe having a probe diameter of 5 mmΦ is pressed against the pressure-sensitive adhesive layer 20 of the pressure-sensitive adhesive tape at a contact speed of 120 mm/min to apply a load of 10 gf so that the probe is kept in contact with the pressure-sensitive adhesive layer 20 for 1 second. Next, the probe is pulled up at a peel rate of 600 mm/min, and a peak top value at the time of the peeling is defined as the tack value T_{A} (gf), and an area of the peak is defined as the integrated value I_{A} (gf·sec). Thus, each value is determined.

In the pressure-sensitive adhesive tape for semiconductor wafer processing according to at least one embodiment of the present invention, the quotient Y (I_{A}/T_{A}) between the tack value T_{A} (gf) and the integrated value I_{A} (gf·sec) preferably satisfies the following formula (2). The pressure-sensitive adhesive tape for semiconductor wafer processing that satisfies a relationship of the formula (2) is more excellent in unevenness-embedding property, and can be further suppressed from creating adhesive residue on the surface of the semiconductor wafer.

$$Y < 0.02 X - 0.33 \qquad ( 2 )$$

In the pressure-sensitive adhesive tape for semiconductor wafer processing according to at least one embodiment of the present invention, the quotient Y (I_{A}/T_{A}) between the tack value T_{A} (gf) and the integrated value I_{A} (gf·sec) preferably satisfies the following formula (3). The pressure-sensitive adhesive tape for semiconductor wafer processing that satisfies a relationship of the formula (3) is more excellent in unevenness-embedding property, and can be further suppressed from creating adhesive residue on the surface of the semiconductor wafer.

$$Y > - 0.012 X + 0.288 \qquad ( 3 )$$

In the pressure-sensitive adhesive tape for semiconductor wafer processing according to at least one embodiment of the present invention, the quotient Y (I_{A}/T_{A}) between the tack value T_{A} (gf) and the integrated value I_{A} (gf·sec) preferably satisfies the following formula (4). The pressure-sensitive adhesive tape for semiconductor wafer processing that satisfies a relationship of the formula (4) is more excellent in unevenness-embedding property, and can be further suppressed from creating adhesive residue on the surface of the semiconductor wafer.

$$Y < 0.0107 X - 0.1861 \qquad ( 4 )$$

The pressure-sensitive adhesive tape for semiconductor wafer processing according to at least one embodiment of the present invention may further include any appropriate layer except the base material 10, the intermediate layer, and the pressure-sensitive adhesive layer 20. The tape may further include, for example, an antistatic layer. The presence of the antistatic layer can prevent the electrostatic breakdown of a semiconductor element due to static electricity at the time of the peeling of the pressure-sensitive adhesive tape for semiconductor wafer processing.

The thickness of the pressure-sensitive adhesive tape for semiconductor wafer processing may be set to any appropriate range, and is preferably from 10 μm to 1, 000 μm, more preferably from 30 μm to 300 μm, still more preferably from 40 μm to 200 μm. B. Base Material

The base material 10 may include any appropriate resin. Specific examples of the resin for forming the base material 10 include polyester-based resins, such as polyethylene terephthalate (PET), polyethylene naphthalate (PEN), polybutylene terephthalate (PBT), and polybutylene naphthalate (PBN), polyolefin-based resins, such as an ethylene-vinyl acetate copolymer, an ethylene-methyl methacrylate copolymer, polyethylene, polypropylene, and an ethylene-propylene copolymer, polyvinyl alcohol, polyvinylidene chloride, polyvinyl chloride, a vinyl chloride-vinyl acetate copolymer, polyvinyl acetate, polyamide, polyimide, celluloses, a fluorine-based resin, polyether, polystyrene-based resins such as polystyrene, polycarbonate, and polyether sulfone. Of those, polyethylene terephthalate, polyethylene naphthalate, polybutylene terephthalate, and polybutylene naphthalate are preferably used.

The base material 10 may further include any other component to the extent that the effects of the present invention are not impaired. Examples of the other component include an antioxidant, a UV absorber, a light stabilizer, and a heat stabilizer. The other component may be used in any appropriate amount in accordance with purposes.

In at least one embodiment of the present invention, the base material 10 has an antistatic function. When the base material 10 has an antistatic function, an occurrence of static electricity at the time of peeling of the tape is suppressed, and breakdown of a circuit by static electricity and adhesion of foreign matter can be prevented. The base material 10 may have an antistatic function by being formed of a resin containing an antistatic agent, or may have an antistatic function by applying a composition containing an antistatic component, such as a conductive polymer, an organic or inorganic conductive substance, or an antistatic agent, to any appropriate film to form an antistatic layer. When the base material 10 includes the antistatic layer, the intermediate layer is preferably laminated on a surface on which the antistatic layer is formed. When the base material 10 has an antistatic function, the base material 10 has a surface resistance value of, for example, from 1.0×10² Ω/}to 1.0×10¹³ Ω/□.

The thickness of the base material 10 may be set to any appropriate value. The thickness of the base material 10 is preferably from 10 μm to 200 μm, more preferably from 20 μm to 150 μm.

The modulus of elasticity of the base material 10 may be set to any appropriate value. The modulus of elasticity of the base material 10 is preferably from 50 MPa to 6,000 MPa, more preferably from 70 MPa to 5,000 MPa. When the modulus of elasticity falls within the above-mentioned ranges, a pressure-sensitive adhesive tape for semiconductor wafer processing that can appropriately follow the unevenness of an adherend surface can be obtained.

### C. Pressure-sensitive Adhesive Layer

The pressure-sensitive adhesive layer 20 may be formed by using any appropriate active energy ray-curable pressure-sensitive adhesive. The pressure-sensitive adhesive typically contains a base polymer. When the pressure-sensitive adhesive layer 20 is formed of the active energy ray-curable pressure-sensitive adhesive, a pressure-sensitive adhesive tape for semiconductor wafer processing excellent in light peelability can be obtained.

The storage modulus of elasticity of the pressure-sensitive adhesive layer 20 before active energy ray irradiation is preferably from 0.020 MPa to 0.25 MPa, more preferably from 0.025 MPa to 0.20 MPa, still more preferably from 0.03 MPa to 0.18

MPa. When the storage modulus of elasticity falls within the above-mentioned ranges, the pressure-sensitive adhesive layer 20 can be satisfactorily brought into close contact with the semiconductor wafer serving as the adherend. The storage modulus of elasticity of the pressure-sensitive adhesive layer 20 may be measured with, for example, a viscoelasticity-measuring apparatus.

A contact angle with water of the pressure-sensitive adhesive layer 20 is preferably from 95° to 125°, more preferably from 100° to 120°. In addition, a contact angle with methylene iodide of the pressure-sensitive adhesive layer 20 is preferably from 55° to 85°, more preferably from 60° to 80°.

The surface free energy X of the pressure-sensitive adhesive layer 20 may be set to any appropriate value so that the formula (1) is satisfied. The surface free energy X is preferably from 10 mN/m to 40 mN/m, more preferably from 15 mN/m to 30 mN/m, still more preferably from 20 mN/m to 25 mN/m. When the surface free energy of the pressure-sensitive adhesive layer 20 falls within the above-mentioned ranges, the affinity to a surface of the semiconductor wafer serving as the adherend is adjusted to an appropriate range, an appropriate pressure-sensitive adhesive strength is exhibited when the pressure-sensitive adhesive layer 20 is bonded to an adherend, and hence an adhesive residue on the adherend after the peeling of the pressure-sensitive adhesive tape can be suppressed. The surface free energy X of the pressure-sensitive adhesive layer 20 as used herein refers to a value calculated by the following method. The contact angle with water and contact angle with methylene iodide of the pressure-sensitive adhesive layer 20 are each measured. The obtained measured value and a surface free energy value (literature value) of a liquid for measuring the contact angle (water or methylene iodide) are substituted into the following equation (I) derived from Young's equation and extended Fowkes' equation. Two equations obtained from the contact angle with water and the contact angle with methylene iodide are solved as a simultaneous linear equation to calculate the surface free energy value. The surface free energy yS of a solid is a sum of yS^{d} and yS^{v}.

$$( 1 + cos θ ) {γ}_{L} = 2 √ ( γ {S}^{d} γ {L}^{d} ) + 2 √ ( {γ}_{S}^{v} {γ}_{L}^{v} ) \qquad ( I )$$

The respective symbols in the equation are as described below.
θ: contact angle
Y_{L}: surface free energy of liquid for measuring contact angle
YL^{d}: dispersion force component in YL
Y_{L}^{v}: polar force component in VL
YS^{d}: dispersion force component in surface free energy of solid
YS^{v}: polar force component in surface free energy of solid

The tack value T_{A} of the pressure-sensitive adhesive layer 20 measured by the probe tack method is preferably from 150 gf to 900 gf, more preferably from 200 gf to 850 gf, still more preferably from 250 gf to 850 gf. When the tack value T_{A} of the pressure-sensitive adhesive layer 20 falls within the above-mentioned ranges, the pressure-sensitive adhesive layer 20 can be satisfactorily brought into close contact with the semiconductor wafer serving as the adherend. The tack value T_{A} of the pressure-sensitive adhesive layer 20 measured by the probe tack method may be measured by the above-mentioned method.

The integrated value I_{A} of the pressure-sensitive adhesive layer 20 measured by the probe tack method is preferably from 5 gf·sec to 50 gf·sec, more preferably from 5 gf·sec to 45 gf·sec. When the integrated value I_{A} of the pressure-sensitive adhesive layer 20 measured by the probe tack method falls within the above-mentioned ranges, the deformation energy of the pressure-sensitive adhesive layer 20 may increase. The integrated value I_{A} measured by the probe tack method may be measured by the above-mentioned method.

The quotient Y (I_{A}/T_{A}) between the tack value T_{A} (gf) and the integrated value I_{A} (gf·sec) may be set to any appropriate value so that the formula (1) is satisfied. The quotient Y is preferably from 0.01 to 0.08, more preferably from 0.02 to 0.07, still more preferably from 0.03 to 0.06. When the quotient Y falls within the above-mentioned ranges, a pressure-sensitive adhesive layer 20 which is excellent in adhesiveness to the surface of an adherend and unevenness-embedding property, and in which the adhesive residue on the semiconductor wafer serving as the adherend is reduced can be obtained.

Any appropriate pressure-sensitive adhesive may be used as the active energy ray-curable pressure-sensitive adhesive. For example, a pressure-sensitive adhesive obtained by adding a UV-curable monomer oligomer to any appropriate pressure-sensitive adhesive, such as an acrylic pressure-sensitive adhesive, a rubber-based pressure-sensitive adhesive, a silicone-based pressure-sensitive adhesive, or a polyvinyl ether-based pressure-sensitive adhesive, may be adopted, or a pressure-sensitive adhesive using a polymer having a polymerizable carbon-carbon double bond introduced into a side chain thereof and/or a terminal thereof as a base polymer may be adopted. Of those, a pressure-sensitive adhesive using a polymer having a polymerizable carbon-carbon double bond introduced into a side chain thereof and/or a terminal thereof as a base polymer is preferably used.

When the pressure-sensitive adhesive using a polymer having a polymerizable carbon-carbon double bond introduced into a side chain thereof and/or a terminal thereof is used, a polymer having a polymerizable carbon-carbon double bond introduced into a side chain thereof and/or a terminal thereof and having a pressure-sensitive adhesive property is used as the base polymer. Examples of such polymer include polymers each obtained by introducing a polymerizable carbon-carbon double bond into a resin, such as an acrylic resin, a vinyl alkyl ether-based resin, a silicone-based resin, a polyester-based resin, a polyamide-based resin, a urethane-based resin, or a styrene-diene block copolymer. Of those, an acrylic resin obtained by introducing a polymerizable carbon-carbon double bond into an acrylic resin is preferably used. When the acrylic resin is used, a pressure-sensitive adhesive tape in which the storage modulus of elasticity and tensile modulus of elasticity of the pressure-sensitive adhesive layer 20 are easily adjusted, and which is excellent in balance between a pressure-sensitive adhesive strength and peelability can be obtained. Further, contamination of a semiconductor wafer by a component derived from the pressure-sensitive adhesive can be reduced. C-1. Base Polymer

Any appropriate polymer may be used as the base polymer. The base polymer may be obtained by polymerizing any appropriate monomer composition. As described above, a (meth) acrylic polymer is preferably used as the base polymer. The term “(meth) acrylic” as used herein refers to “acrylic” and/or “methacrylic”.

The monomer composition to be used for the polymerization of the base polymer may contain any appropriate monomer. The monomer composition preferably contains, as a monomer component, a (meth) acrylic monomer having a side chain having 8 or more carbon atoms. Any appropriate monomer may be used as the (meth) acrylic monomer having a side chain having 8 or more carbon atoms. Examples thereof include 2-ethylhexyl acrylate, octyl (meth) acrylate, isooctyl (meth) acrylate, nonyl (meth) acrylate, isononyl (meth) acrylate, decyl (meth) acrylate, isodecyl (meth) acrylate, and dodecyl (meth) acrylate. The (meth) acrylic monomers each having a side chain having 8 or more carbon atoms may be used alone or in combination thereof.

The content ratio of the (meth) acrylic monomer having a side chain having 8 or more carbon atoms in the monomer composition may be set to any appropriate value. The content ratio of the (meth) acrylic monomer having a side chain having 8 or more carbon atoms is preferably 60 mol % or more, more preferably 70 mol % or more, still more preferably 80 mol % or more with respect to 100 mol % of a total of all monomer components. The content ratio of the (meth) acrylic monomer having a side chain having 8 or more carbon atoms is, for example, less than 90 mol %. When the content ratio of the (meth) acrylic monomer having a side chain having 8 or more carbon atoms falls within the above-mentioned ranges, the surface energy X can be adjusted to an appropriate value, and hence a pressure-sensitive adhesive tape for semiconductor wafer processing that is excellent in unevenness-embedding property, and is suppressed from creating adhesive residue on the surface of a semiconductor wafer can be provided.

The monomer composition may contain any appropriate other monomer except the (meth) acrylic monomer having a side chain having 8 or more carbon atoms. Examples of the other monomer include a monomer having a side chain having 2 or less carbon atoms and a high-polarity monomer. Any appropriate monomer may be used as the monomer having a side chain having 2 or less carbon atoms. Examples thereof include methyl (meth)acrylate and ethyl (meth) acrylate. The monomers each having a side chain having 2 or less carbon atoms may be used alone or in combination thereof.

Any appropriate monomer may be used as the high-polarity monomer. Examples thereof include a hydroxy group-containing monomer, a carboxyl group-containing monomer, and a nitrogen-containing monomer. The high-polarity monomer may have 2 or more polar groups (e.g., a hydroxy group and a nitrogen-containing group). The high-polarity monomer is preferably a high-polarity monomer having a side chain having 4 or less carbon atoms, more preferably a hydroxy group-containing monomer having a side chain having 4 or less carbon atoms. The high-polarity monomers may be used alone or in combination thereof.

Any appropriate monomer may be used as the hydroxy group-containing monomer. Specific examples thereof include 2-hydroxyethyl (meth)acrylate, 2-hydroxypropyl (meth) acrylate, 4-hydroxybutyl (meth) acrylate, and N-(2-hydroxyethyl) acrylamide. The hydroxy group-containing monomers may be used alone or in combination thereof.

Any appropriate monomer may be used as the carboxyl group-containing monomer. Specific examples thereof include (meth) acrylic acid, carboxyethyl (meth) acrylate, carboxypentyl (meth) acrylate, itaconic acid, maleic acid, fumaric acid, and crotonic acid. The carboxy group-containing monomers may be used alone or in combination thereof.

Any appropriate monomer may be used as the nitrogen-containing monomer. Specific examples thereof include N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, (meth) acryloylmorpholine, N-vinyl carboxylic acid amides, N-vinylcaprolactam, N-(2-hydroxyethyl) acrylamide, and N, N-dimethylacrylamide. The nitrogen-containing monomers may be used alone or in combination thereof.

The content ratio of at least one kind selected from the group consisting of: the monomer having a side chain having 2 or less carbon atoms; and the high-polarity monomer (total of those content ratios) in the monomer composition may be set to any appropriate value. The content ratio of at least one kind selected from the group consisting of: the monomer having a side chain having 2 or less carbon atoms; and the high-polarity monomer in the monomer composition is preferably 39 mol % or less, more preferably 30 mol % or less, still more preferably 20 mol % or less with respect to 100 mol % of a total of all monomer components. When the content ratio (total content ratio) of at least one kind selected from the group consisting of: the monomer having a side chain having 2 or less carbon atoms; and the high-polarity monomer falls within the above-mentioned ranges, the surface energy X can be adjusted to an appropriate value, and hence a pressure-sensitive adhesive tape for semiconductor wafer processing that is excellent in unevenness-embedding property, and is suppressed from creating adhesive residue on the surface of a semiconductor wafer can be provided.

In at least one embodiment of the present invention, the hydroxy group-containing monomer is preferably used as the high-polarity monomer. When the hydroxy group-containing monomer is used, a (meth) acrylic polymer having a polymerizable carbon-carbon double bond introduced into a side chain thereof and/or a terminal thereof may be obtained by further subjecting the hydroxy group-containing monomer to a reaction with a compound having an isocyanate group as described later. The content ratio of the hydroxy group-containing monomer is preferably 39 mol % or less, more preferably from 10 mol % to 39 mol % with respect to 100 mols of a total of all monomer components. When the content ratio of the hydroxy group-containing monomer falls within the above-mentioned ranges, after the active energy ray irradiation, an adhesive residue on the surface of the semiconductor wafer serving as the adherend can be further suppressed at the time of the peeling of the pressure-sensitive adhesive tape for semiconductor wafer processing.

The monomer further contain any composition may appropriate other monomer. Examples of the other monomer include: acid anhydride monomers, such as maleic anhydride and itaconic anhydride; and functional group-containing monomers including sulfonic acid group-containing monomers, such as styrenesulfonic acid, allyl sulfonic acid, 2-(meth) acrylamido-2-methylpropanesulfonic acid, (meth) acrylamidopropanesulfonic acid, sulfopropyl (meth) acrylate, and (meth) acryloyloxynaphthalenesulfonic acid, and phosphoric acid group-containing monomers such as 2-hydroxyethyl acryloyl phosphate.

As described above, a polymer having a polymerizable carbon-carbon double bond introduced into a side chain thereof and/or a terminal thereof may be used as the base polymer. The polymer having a polymerizable carbon-carbon double bond introduced into a side chain thereof and/or a terminal thereof may be obtained by any appropriate method. The polymer may be obtained by, for example, subjecting a resin obtained by any appropriate polymerization method and a compound having a polymerizable carbon-carbon double bond to a reaction (e.g., a condensation reaction or an addition reaction). Specifically, when the acrylic resin is used, the (meth) acrylic polymer having a polymerizable carbon-carbon double bond introduced thereinto may be obtained by polymerizing a (meth) acrylic polymer (copolymer) having a constituent unit derived from a monomer having any appropriate functional group in any appropriate solvent, and then performing a reaction between a functional group of the (meth) acrylic polymer and the compound having a polymerizable carbon-carbon double bond capable of reacting with the functional group. The amount of the compound having a polymerizable carbon-carbon double bond to be subjected to the reaction is preferably from 4 parts by weight to 30 parts by weight, more preferably from 4 parts by weight to 20 parts by weight with respect to 100 parts by weight of the above-mentioned polymer. Any appropriate solvent may be used as the solvent. Examples thereof include various organic solvents, such as ethyl acetate, methyl ethyl ketone, and toluene.

When the (meth) acrylic polymer and the compound having a polymerizable carbon-carbon double bond are subjected to a reaction as described above, the resin and the compound having a polymerizable carbon-carbon double bond preferably have functional groups capable of reacting with each other. The combination of the functional groups is, for example, a carboxyl group/an epoxy group, a carboxyl group/an aziridine group, or a hydroxyl group/an isocyanate group. Of those combinations of the functional groups, a combination of a hydroxyl group and an isocyanate group is preferred from the viewpoint of ease of reaction tracking.

Examples of the compound having a polymerizable carbon-carbon double bond include 2-isocyanatoethyl methacrylate, methacryloyl isocyanate, 2-methacryloyloxyethyl isocyanate (2-isocyanatoethyl methacrylate), and m-isopropenyl-a, a-dimethylbenzyl isocyanate.

The (meth) acrylic polymer has a weight-average molecular weight of preferably 100,000 or more, more preferably 150, 000 or more, still more preferably 200,000 or more, particularly preferably from 250,000 to 1,000,000. When the weight-average molecular weight falls within such ranges, bleeding of a low-molecular-weight component can be prevented, and hence a pressure-sensitive adhesive tape for semiconductor wafer processing that has a low contamination property can be obtained. The weight-average molecular weight may be determined by gel permeation chromatography measurement (solvent: tetrahydrofuran, polystyrene equivalent).

The gel fraction of the (meth) acrylic polymer is preferably 75% or more, more preferably 80% or more, still more preferably 82% or more. The gel fraction of the (meth) acrylic polymer is preferably 90% or less. When the gel fraction falls within the above-mentioned ranges, a pressure-sensitive adhesive tape for semiconductor wafer processing that is excellent in unevenness-embedding property, and is suppressed from creating adhesive residue on the surface of a semiconductor wafer can be provided.

The (meth) acrylic polymer may be obtained by polymerizing the above-mentioned monomer composition by any appropriate method. Examples thereof include solution polymerization, suspension polymerization, emulsion polymerization, and bulk polymerization. A reaction temperature and a reaction time may be set to any appropriate values in accordance with the weight-average molecular weight and gel fraction of the (meth) acrylic polymer to be obtained, and the kind of the monomer to be used. In addition, the weight-average molecular weight and/or gel fraction of the (meth) acrylic polymer to be obtained may be adjusted to any appropriate value by adjusting, for example, reaction conditions, such as a reaction temperature and a reaction time, and/or the solid content concentration of the monomer composition to be used.

### C-2. Photopolymerization Initiator

The active energy ray-curable pressure-sensitive adhesive for forming the pressure-sensitive adhesive layer 20 preferably further contains a photopolymerization initiator. Any appropriate initiator may be used as the photopolymerization initiator.

Examples of the photopolymerization initiator include: acyl phosphine oxide-based photoinitiators, such as ethyl 2, 4, 6-trimethylbenzoylphenyl phosphinate and (2, 4, 6-trimethylbenzoyl)-phenylphosphine oxide; x-ketol-based compounds, such as 4-(2-hydroxyethoxy) phenyl (2-hydroxy-2-propyl) ketone, a-hydroxy-a, a′-dimethylacetophenone, 2-methyl-2-hydroxypropiophenone, and 1-hydroxycyclohexyl phenyl ketone; acetophenone-based compounds, such as methoxyacetophenone, 2, 2-dimethoxy-2-phenylacetophenone, 2, 2-diethoxyacetophenone, and 2-methyl-1-[4-(methylthio)-phenyl]-2-morpholinopropane-1; benzoin ether-based compounds, such as benzoin ethyl ether, benzoin isopropyl ether, and anisoin methyl ether; ketal-based compounds, such as benzyl dimethyl ketal; aromatic sulfonyl chloride-based compounds, such as 2-naphthalenesulfonyl chloride; photoactive oxime-based compounds such as 1-Phenyl-1, 2-propanedione-2-(0-ethoxycarboxy) oxime; benzophenone-based compounds, such as benzophenone, benzoylbenzoic acid, and 3, 3′-dimethyl-4-methoxybenzophenone; thioxanthone-based compounds, such as thioxanthone, 2-chlorothioxanthone, 2-methylthioxanthone, 2, 4-dimethylthioxanthone, isopropylthioxanthone, 2, 4-dichlorothioxanthone, 2,4-diethylthioxanthone, and 2, 4-diisopropylthioxanthone; camphorquinone; halogenated ketones; and acyl phosphonates, and x-hydroxyacetophenones, such as 2-hydroxy-1-(4-(4-(2-hydroxy-2-methylpropionyl)benzyl)phenyl-2-methylpropane-1. Of those, 2, 2-dimethoxy-2-phenylacetophenone and 2-hydroxy-1-(4-(4-(2-hydroxy-2-methylpropionyl)benzyl)phenyl-2-methylpropane-1 may be preferably used. The photopolymerization initiators may be used alone or in combination thereof.

A commercially available product may also be used as the photopolymerization initiator. Examples thereof include products available under the product names of Omnirad 127D, Omnirad 651, Omnirad 369E, and Omnirad 819 from IGM Resins B.V.

The photopolymerization initiator is used in any appropriate amount. The content of the photopolymerization initiator is preferably from 0.5 part by weight to 20 parts by weight, more preferably from 0.5 part by weight to 10 parts by weight with respect to 100 parts by weight of the base polymer. When the content of the photopolymerization initiator is less than 0.5 part by weight, the active energy ray-curable pressure-sensitive adhesive may not be sufficiently cured at the time of UV irradiation. When the content of the photopolymerization initiator is more than 10 parts by weight, the storage stability of the pressure-sensitive adhesive may reduce.

### C-3. Additive

The pressure-sensitive adhesive may contain any appropriate additive as required. Examples of the additive include a cross-linking agent, a catalyst (e.g., a platinum catalyst), a tackifier, a plasticizer, a pigment, a dye, a filler, an age resistor, a conductive material, a UV absorber, a light stabilizer, a peeling modifier, a softener, a surfactant, a flame retardant, and a solvent.

In at least one embodiment of the present invention, the pressure-sensitive adhesive further contains a cross-linking agent. Examples of the cross-linking agent include an isocyanate-based cross-linking agent, an epoxy-based cross-linking agent, an aziridine-based cross-linking agent, and a chelate-based cross-linking agent. The content ratio of the cross-linking agent is preferably from 0.01 part by weight to 10 parts by weight, more preferably from 0.02 part by weight to 5 parts by weight, still more preferably from 0.025 part by weight to 0.5 part by weight with respect to 100 parts by weight of the base polymer in the pressure-sensitive adhesive. The flexibility of the pressure-sensitive adhesive layer 20 may be controlled by the content ratio of the cross-linking agent. When the content of the cross-linking agent is less than 0.01 part by weight, the pressure-sensitive adhesive becomes sol, and hence the pressure-sensitive adhesive layer 20 may not be formed. When the content of the cross-linking agent is more than 10 parts by weight, adhesiveness to a semiconductor wafer may reduce, and hence the semiconductor wafer may not be sufficiently protected.

In at least one embodiment of the present invention, the isocyanate-based cross-linking agent is preferably used. The isocyanate-based cross-linking agent is preferred because the cross-linking agent can react with various kinds of functional groups.A cross-linking agent having 3 or more isocyanate groups is particularly preferably used. When the isocyanate-based cross-linking agent is used as the cross-linking agent and the content ratio of the cross-linking agent falls within the above-mentioned ranges, a pressure-sensitive adhesive layer 20 which is excellent in peelability even after heating, and in which the adhesive residue is remarkably reduced can be formed.

The thickness of the pressure-sensitive adhesive layer 20 may be set to any appropriate value. The thickness of the pressure-sensitive adhesive layer 20 is preferably from 1 μm to 50 μm, more preferably from 2 μm to 40 μm, still more preferably from 4 μm to 30 μm. When the thickness of the pressure-sensitive adhesive layer 20 falls within the above-mentioned ranges, a sufficient pressure-sensitive adhesive strength to a semiconductor wafer can be exhibited.

The pressure-sensitive adhesive layer 20 may have any appropriate pressure-sensitive adhesive strength. The pressure-sensitive adhesive strength of the pressure-sensitive adhesive layer 20 to a silicon wafer before UV irradiation is preferably from 0.50 N/20 mm to 30 N/20 mm, more preferably from 2 N/20 mm to 25 N/20 mm, still more preferably from 5 N/20 mm to 25 N/20 mm. The pressure-sensitive adhesive strength of the pressure-sensitive adhesive layer 20 as used herein refers to a value measured as follows: the pressure-sensitive adhesive tape for semiconductor wafer processing is cut out into a size of 20 mm wide by 80 mm long; the pressure-sensitive adhesive layer 20 of the pressure-sensitive adhesive tape for semiconductor wafer processing is pressure-bonded to a mirror surface of a silicon mirror wafer by reciprocating a 2-kilogram roller once under an atmosphere at 23° C.; the resultant is left to stand at 23° C. for 30 minutes; and then measurement is performed by a 180° peel test under an atmosphere at 23° C. and 50% RH and under the condition of a tensile rate of 300 mm/min.

The pressure-sensitive adhesive strength of the pressure-sensitive adhesive layer 20 to the silicon wafer after UV irradiation is preferably from 0.001 N/20 mm to 1.000 N/20 mm, more preferably from 0.005 N/20 mm to 0.850 N/20 mm, still more preferably from 0.03 N/20 mm to 0.40 N/20 mm. The pressure-sensitive adhesive strength after UV irradiation as used herein refers to a value measured as follows: the pressure-sensitive adhesive tape for semiconductor wafer processing is cut out into a size of 20 mm wide by 80 mm long, and the pressure-sensitive adhesive layer 20 is pressure-bonded to a mirror surface of a silicon mirror wafer by reciprocating a 2-kilogram roller once under an atmosphere at 23° C.; the resultant is left to stand at 23° C. for 30 minutes; then the pressure-sensitive adhesive layer 20 is irradiated with UV light (UV) from a base material side of the pressure-sensitive adhesive tape for semiconductor wafer processing so that the integrated light quantity becomes 1,000 mJ/cm² (in terms of 365 nm); and then measurement is performed by performing a 180° peel test under an atmosphere at 23° C. and 50% RH and under the condition of a tensile rate of 300 mm/min.

### D. Intermediate Layer

In at least one embodiment of the present invention, the pressure-sensitive adhesive tape for semiconductor wafer processing preferably further includes the intermediate layer 30. In the case where the pressure-sensitive adhesive tape for semiconductor wafer processing further includes the intermediate layer 30, when the surface of an adherend has unevenness, the tape can be further improved in unevenness-embedding property.

The intermediate layer 30 may be formed of any appropriate material. The intermediate layer 30 may be formed of any appropriate resin, such as an acrylic resin, a polyethylene-based resin, an ethylene-vinyl alcohol copolymer, an ethylene-vinyl acetate-based resin, or an ethylene-methyl methacrylate resin, or may be formed of a pressure-sensitive adhesive such as an acrylic pressure-sensitive adhesive. The acrylic pressure-sensitive adhesive is preferably used. The acrylic pressure-sensitive adhesive typically contains an acrylic base polymer.

In at least one embodiment of the present invention, the intermediate layer 30 contains a photopolymerization initiator and is free from a UV-curable component. That is, the intermediate layer 30 itself is not cured by UV irradiation, though the layer contains the photopolymerization initiator. Accordingly, the intermediate layer 30 can maintain flexibility before and after UV irradiation. In addition, when the intermediate layer 30 contains the photopolymerization initiator, the photopolymerization initiator in the pressure-sensitive adhesive layer 20 transfers to the intermediate layer 30 can be suppressed. As a result, reduction of the content of the photopolymerization initiator in the pressure-sensitive adhesive layer 20 with time can be suppressed. Accordingly, the pressure-sensitive adhesive tape for semiconductor wafer processing can exhibit excellent light peelability after UV irradiation. The UV-curable component as used herein refers to a component that may be cross-linked by UV irradiation and shrink by curing. The component is specifically, for example, the polymer having an unsaturated carbon double bond in a side chain thereof or at a terminal thereof described above.

The photopolymerization initiator in the composition for forming the intermediate layer 30 may be identical to or different from the photopolymerization initiator in the pressure-sensitive adhesive layer 20. The intermediate layer 30 and the pressure-sensitive adhesive layer) preferably contain the same photopolymerization initiator. When the intermediate layer 30 and the pressure-sensitive adhesive layer 20 contain the same photopolymerization initiator, transfer of the photopolymerization initiator from the pressure-sensitive adhesive layer 20 to the intermediate layer 30 can be further suppressed. The photopolymerization initiator taken as an example in the above-mentioned section C-2. may be used as the photopolymerization initiator. The photopolymerization initiators may be used alone or in combination thereof. The content of the photopolymerization initiator in the intermediate layer 30 is preferably from 0.1 part by weight to 10 parts by weight, more preferably from 0.5 part by weight to 8 parts by weight with respect to 100 parts by weight of a polymer constituent component in the composition for forming the intermediate layer 30. When the content of the photopolymerization initiator in the intermediate layer 30 falls within the above-mentioned ranges, a pressure-sensitive adhesive tape for semiconductor wafer processing that has excellent light peelability after UV irradiation can be obtained. In at least one embodiment of the present invention, the photopolymerization initiator is used in an equal amount to that in the composition for forming the pressure-sensitive adhesive layer 20.

In at least one embodiment of the present invention, the composition for forming the intermediate layer 30 further contains a cross-linking agent. Examples of the cross-linking agent include an isocyanate-based cross-linking agent, an epoxy-based cross-linking agent, an oxazoline-based cross-linking agent, an aziridine-based cross-linking agent, melamine-based cross-linking agent, a peroxide-based cross-linking agent, a urea-based cross-linking agent, a metal alkoxide-based cross-linking agent, a metal chelate-based cross-linking agent, a metal salt-based cross-linking agent, a carbodiimide-based cross-linking agent, and an amine-based cross-linking agent. When the composition for forming the intermediate layer 30 contains the cross-linking agent, the content ratio of the cross-linking agent is preferably from 0.5 part by weight to 10 parts by weight, more preferably from 1 part by weight to 8 parts by weight with respect to 100 parts by weight of the polymer constituent component in the composition for forming the intermediate layer 30.

The composition for forming the intermediate layer 30 may further contain any appropriate additive as required. Examples of the additive include an active energy ray polymerization accelerator, a radical scavenger, a tackifier, a plasticizer (e.g., a trimellitic acid ester-based plasticizer or a pyromellitic acid ester-based plasticizer), a pigment, a dye, a filler, an age resistor, a conductive material, an antistatic agent, a UV absorber, a light stabilizer, a peeling modifier, a softener, a surfactant, a flame retardant, and an antioxidant.

The thickness of the intermediate layer 30 may be set to any appropriate value. The thickness of the intermediate layer 30 is preferably from 10 μm to 300 μm, more preferably from 30 μm to 200 μm, still more preferably from 50 μm to 150 μm, particularly preferably from 90 μm to 150 μm. When the thickness of the intermediate layer 30 falls within the above-mentioned ranges, a pressure-sensitive adhesive tape for semiconductor wafer processing that can satisfactorily embed an uneven surface can be obtained.

E. Method of producing Pressure-sensitive Adhesive Tape for Semiconductor Wafer Processing

The pressure-sensitive adhesive tape for semiconductor wafer processing may be produced by any appropriate method. In at least one embodiment of the present invention, the pressure-sensitive adhesive tape for semiconductor wafer processing may be produced by, for example, forming any appropriate intermediate layer 30 on the base material 10, and then forming the pressure-sensitive adhesive layer 20 on the base material 10 or any appropriate intermediate layer 30. The pressure-sensitive adhesive layer 20 and the intermediate layer 30 may be formed by applying the composition for forming the pressure-sensitive adhesive layer 20 and the composition for forming the intermediate layer 30 to the base material 10 and the intermediate layer 30, respectively, or may each be formed by forming the layer on any appropriate release liner and then transferring the layer. Various methods, such as bar coater coating, air knife coating, gravure coating, gravure reverse coating, reverse roll coating, lip coating, die coating, dip coating, offset printing, flexographic printing, and screen printing, may each be adopted as a method for the application. In addition, for example, a method involving separately forming the pressure-sensitive adhesive layer 20 or the intermediate layer 30 on the release liner and then bonding the resultant to the base material 10 may be adopted.

### F. Applications of Pressure-sensitive Adhesive Tape for Semiconductor Wafer Processing

The pressure-sensitive adhesive tape for semiconductor wafer processing according to at least one embodiment of the present invention may be suitably used in a semiconductor element production process. The pressure-sensitive adhesive tape for semiconductor wafer processing according to at least one embodiment of the present invention may be suitably used as a backgrinding tape. The backgrinding tape is required to have such light peelability as to appropriately hold a silicon wafer at the time of backgrinding and to be capable of being peeled without creating adhesive residue and without breaking the ground wafer at the time of its peeling. The pressure-sensitive adhesive tape for semiconductor wafer processing according to at least one embodiment of the present invention is excellent in unevenness-embedding property, and can be suppressed from creating adhesive residue on the surface of a semiconductor wafer. Accordingly, the pressure-sensitive adhesive tape for semiconductor wafer processing according to at least one embodiment of the present invention may be suitably used as a backgrinding tape.

### EXAMPLES

The present invention is specifically described below by way of examples, but the present invention is not limited to these examples. In addition, in the examples, “part(s)” and “%” are by weight unless stated otherwise.

### Example 1

1. Preparation of Composition for forming Intermediate Layer

50 parts by weight of butyl acrylate (BA), 50 parts by weight of ethyl acrylate (EA), 5 parts by weight of acrylic acid (AA), and 0.1 part by weight of azobisisobutyronitrile (AIBN) were subjected to polymerization in toluene under a nitrogen atmosphere at 60° C. for 6 hours to provide a polymer solution containing a (meth) acrylic polymer having a weight-average molecular weight of 650,000.

1 part by weight of a polyisocyanate compound (manufactured by Mitsui Chemicals Inc., product name: “TAKENATE D-101A”) and 1 part by weight of a photopolymerization initiator (manufactured by IGM Resins B.V., product name: Omnirad 127D) with respect to 100 parts by weight of the solid content of the resultant polymer solution were mixed. Thus, a composition for forming the intermediate layer 30 containing toluene (solid content concentration: 23%) was obtained.

### 2. Preparation of Pressure-sensitive Adhesive Composition

89 wt % of 2-ethylhexyl acrylate (2EHA) and 11 wt % of 2-hydroxyethyl acrylate (HEA) (manufactured by Toagosei Co., Ltd., product name: ACRYCS (trademark) HEA) were each used as a monomer component. 0.15 wt % of a polymerization initiator (manufactured by Tokyo Chemical Industry Co., Ltd., product name: 2, 2′-azobis (isobutyronitrile) (AIBN)) with respect to the total weight of the monomer components, and a solvent (ethyl acetate) were mixed to prepare a monomer composition (solid content concentration: 32%). The resultant monomer composition was loaded into an experimental apparatus for polymerization obtained by mounting a 1-liter round-bottom separable flask with a separable cover, a separating funnel, a temperature gauge, a nitrogen-introducing tube, a Liebig condenser, a vacuum seal, a stirring rod, and a stirring blade. While the composition was stirred, the apparatus was purged with nitrogen at normal temperature for 1 hour. After that, while the composition was stirred in a stream of nitrogen, the composition was held at 67° C. for 5 hours to be subjected to solution polymerization, and was then increased in temperature to 76° C. and held at 76° C. for 2 hours to provide a polymer solution.

The resultant polymer solution was cooled to 35° C. or less, and was stirred for 15 minutes or more while oxygen was introduced into the flask. After that, 2-methacryloyloxyethyl isocyanate (hereinafter referred to as “MOI”) (manufactured by Resonac Corporation, product name: “karenz MOI”) was added so that its amount became 80 mol % in terms of moles with respect to the addition amount of HEA. In addition, 0.03 wt % of dibutyltin dilaurate with respect to the addition amount of MOI was added as a reaction catalyst. After that, the contents were subjected to addition reaction treatment (urethanization reaction) at 50° C. for 12 hours in a stream of air to provide a UV light (UV)-curable acrylic copolymer.

Next, 2 parts by weight of a photopolymerization initiator (manufactured by IGM Resins B.V., product name: “Omnirad 127D”), 1 part by weight of a polyisocyanate compound (manufactured by Mitsui Chemicals Inc., product name: “TAKENATE D-101A”), and 0.01 part by weight of an antioxidant (manufactured by BASF Japan Ltd., product name: “Irganox 1010”) were added to 100 parts by weight of the UV-curable acrylic copolymer to prepare a pressure-sensitive adhesive composition.

### 3. Production of Tape

The composition for forming the intermediate layer 30 obtained in section 1 was applied to a surface of a polyester-based release liner having a thickness of 38 μm (manufactured by Mitsubishi Chemical product Corporation, name: “Diafoil (trademark)”), the surface having been subjected to silicone treatment, and was heated at 120° C. for 120 seconds so that its solvent was removed. Thus, a first intermediate layer having a thickness of 50 μm was formed. Next, a PET film having a thickness of 50 μm (manufactured by Toray Industries, Inc., product name: “LUMIRROR (trademark)”), the film serving as the base material 10, was bonded to the surface of the first intermediate layer thus formed. Separately, the composition for forming the intermediate layer 30 was applied to a surface of a polyester-based release liner having a thickness of 38 μm, the surface having been subjected to silicone treatment, and was heated at 120° C. for 120 seconds so that its solvent was removed. Thus, a second intermediate layer having a thickness of 50 μm was formed. The release liner was peeled from the first intermediate layer, and the second intermediate layer was bonded to a surface of the first intermediate layer from which the release liner had been peeled. Thus, a laminate of the base material 10 and the intermediate layers 30 (the first intermediate layer and the second intermediate layer) was obtained.

Separately, the pressure-sensitive adhesive composition obtained in section 2 was applied to a surface of a polyester-based release liner having a thickness of 75 μm, the surface having been subjected to silicone treatment, and was heated at 120° C. for 120 seconds so that its solvent was removed. Thus, a pressure-sensitive adhesive layer 20 having a thickness of 20 μm was formed. Next, the release liner was peeled from the second intermediate layer, the pressure-sensitive adhesive layer 20 was bonded to the surface of the second intermediate layer from which the release liner had been peeled to transfer the pressure-sensitive adhesive layer 20, and the resultant was kept at 50° C. for 72 hours. Thus, a pressure-sensitive adhesive tape including the base material 10, the intermediate layers 30 (the first intermediate layer and the second intermediate layer), and the pressure-sensitive adhesive layer 20 in the stated order was obtained.

### Examples 2 to 6

Pressure-sensitive adhesive tapes were each obtained in the same manner as in Example 1 except that the composition of the respective monomers, the polymerization conditions for the monomers, and the composition of the pressure-sensitive adhesive composition were changed as shown in Table 1.

### Comparative Examples 1 to 3

Pressure-sensitive adhesive tapes were each obtained in the same manner as in Example 1 except that the composition of the respective monomers, the polymerization conditions for the monomers, and the composition of the pressure-sensitive adhesive composition were changed as shown in Table 1.

| | | | | | | | | | | |
|---|---|---|---|---|---|---|---|---|---|---|
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] |

[symbol]

indicates data missing or illegible when filed

### <Evaluation>

The following evaluations were performed by using the pressure-sensitive adhesive tapes obtained in Examples and Comparative Examples. The results are shown in Table 1. 1. Measurement of Weight-average Molecular Weight Mw

About 0.2 g of a sample was acquired from the resultant UV-curable acrylic copolymer. The collected sample was dissolved in tetrahydrofuran (THF) to prepare a THF solution so that the solid content concentration became 0.2 wt %, and the solution was left to stand overnight. The THE solution having been left to stand overnight was filtered with a membrane filter having a pore diameter of 0.45 μm, and the resultant filtrate was adopted as a measurement sample.

A weight-average molecular weight Mw of the measurement sample was measured by using HLC-8220GPC manufactured by Tosoh Corporation as an analyzer under the following measurement conditions.
Column: one column of TSKgel guardcolumn SuperHZ-L (hereinafter referred to as “first column”) manufactured by Tosoh Corporation and two columns of TSKgel SuperHZM-M (hereinafter referred to as “second column”) manufactured by Tosoh Corporation

The respective columns were arranged on the analyzer by connecting two second columns in series on a downstream side of the first column so that an eluent flows in from a first column side.
Column temperature: 40° C.
Eluent: tetrahydrofuran (THF)
Flow rate: sample pump flow rate: 0.3 mL/min, reference pump flow rate: 1.0 mL/min
Injection amount: 100 μL
Detector: differential refractive index detector (RI)

In order to obtain a molecular weight distribution curve (differential molecular weight distribution curve) based on the results measured for the measurement samples, the respective reference polystyrenes manufactured by Tosoh Corporation were weighed so as to have the following blending weights as shown in Table 2, and the weighed respective reference polystyrenes were dissolved in 100 mL of THE to provide reference polystyrene solutions STD1 and reference polystyrene solutions STD2. Those solutions were each subjected to GPC measurement in the same manner.

TABLE 2

| STD1 | | | | STD2 | | | |
|---|---|---|---|---|---|---|---|
| Kind of | Weight-average | | | Kind of | Weight-average | | |
| reference | molecular | Blending | | reference | molecular | Blending | |
| polystyrene | weight Mw | weight | | polystyrene | weight Mw | weight | |
| F380 | 3,840,000 | 10 | mg | F450 | 4,480,000 | 10 | mg |
| F128 | 1,110,000 | 10 | mg | F288 | 2,110,000 | 10 | mg |
| F40 | 397,000 | 10 | mg | F80 | 707,000 | 10 | mg |
| F10 | 98,900 | 10 | mg | F20 | 189,000 | 10 | mg |
| F2 | 17,400 | 10 | mg | F450 | 37,200 | 10 | mg |
| A5000 | 4,920 | 10 | mg | F1 | 9,490 | 10 | mg |
| A1000 | 1,013 | 14.8 | mg | A2500 | 2,500 | 10 | mg |
| | | | | A500 | 589 | 19.7 | mg |

### 2. Gel Fraction

About 0.2 g of a sample was collected from the pressure-sensitive adhesive composition before the curing by UV irradiation. Next, the sample was wrapped in a mesh-like sheet (manufactured by Nitto Denko Corporation, product name: NTF1122, thickness: 80 μm, average pore diameter: 0.2 μm), and was then immersed in about 30 mL of ethyl acetate at room temperature for 1 week. After that, the mesh-like sheet was taken out from ethyl acetate, and an ethyl acetate-insoluble content included in the mesh-like sheet was recovered. The recovered ethyl acetate-insoluble content was dried at normal pressure and at 130° C. for about 2 hours. The ethyl acetate-insoluble content was weighed.A gel fraction was calculated by calculating a weight ratio of the gel component by the following equation.

$$Gel fraction ( \% ) = [ \text{} ( weighed value ( g ) of ethyl acetate - insoluble content ) / ( weight ( g ) of acquired sample ) ] \times 100$$

### 3. Storage Modulus of Elasticity

The pressure-sensitive adhesive compositions used in Examples and Comparative Examples were laminated to a thickness of from about 0.8 mm to about 1.0 mm without air bubbles to provide a sample.A storage modulus G′ of elasticity at 25° C. was measured with a viscoelasticity-measuring apparatus (manufactured by T_{A} Instruments, product name: “ARES-G2”) under the following conditions.
Mode: torsion mode
Plate diameter: 7.9 mmΦ
Strain: 0.1% (-50° C.)·
Frequency: 1 Hz
Measurement range:-50° C. to 150° C.

### 4. Contact Angle and Surface Free Energy

The surface free energy of the pressure-sensitive adhesive layer 20 of each of the pressure-sensitive adhesive tapes obtained in Examples and Comparative Examples was measured by the following method. Water or methylene iodide was dropped onto a surface of the pressure-sensitive adhesive layer 20 of the pressure-sensitive adhesive tape, and a contact angle was measured with a contact angle meter (manufactured by Kyowa Interface Science Co., Ltd., product name: CA-X). The measured value and the surface free energy value (known from literatures) of the liquid for measuring the contact angle (water or methylene iodide) were substituted into the following equation (I) derived from Young's equation and extended Fowkes' equation. The obtained two equations were solved as a simultaneous linear equation to calculate the surface free energy value. The surface free energy YS of the solid is a sum of YS^{d} and YS^{v}.

$$( 1 + cos θ ) {γ}_{L} = 2 √ ( γ {S}^{d} γ {L}^{d} ) + 2 √ ( γ {S}^{v} {γ}_{L}^{v} ) \qquad ( I )$$

The respective symbols in the equation are as described below.
θ: contact angle
Y_{L}: surface free energy of liquid for measuring contact angle
YL^{d}: dispersion force component in VL
Y_{L}^{v}: polar force component in VL
YS^{d}: dispersion force component in surface free energy of solid
YS^{v}: polar force component in surface free energy of solid

### 5. Peak Value and Integrated Value

The tack test of the pressure-sensitive adhesive layer 20 was performed by a probe tack method with a probe tack tester (product name: “TAC-II”) manufactured by Rhesca Co., Ltd. under the following measurement conditions.

### (Measurement Conditions)

Probe diameter: 5 mmp
Contact speed: 120 mm/min
Load: 10 gf
Contact time: 1 second
Peel rate: 600 mm/min

Specifically, a base material surface of each pressure-sensitive adhesive tape and a glass slide were bonded to each other via a double-sided tape (manufactured by Nitto Denko Corporation, product name: “No. 5000NS”) so that the pressure-sensitive adhesive tape was fixed to the glass slide. Next, a probe having a probe diameter of 5 mmΦ was pressed against the pressure-sensitive adhesive layer 20 of the pressure-sensitive adhesive tape at a contact speed of 120 mm/min to apply a load of 10 gf so that the probe was kept in contact with the pressure-sensitive adhesive layer 20 for 1 second. Next, the probe was pulled up at a peel rate of 600 mm/min, and a peak top value (peak value [gf]) at the time of the peeling was defined as a tack value T_{A} (gf), and an area of the peak (integral [gf·sec]) was defined as an integrated value I_{A} (gf·sec). Thus, each value was determined.

### 6. Embedding Property

The pressure-sensitive adhesive tapes obtained in Examples and Comparative Examples were each cut out into 230 cm by 400 cm. The pressure-sensitive adhesive tape having been cut out was bonded to a wafer (8 inch, bump height: 75 μm, diameter: 90 μm, pitch: 200 μm) with a tape-bonding apparatus (manufactured by Nitto Seiki Co., Ltd., product name: DR-3000III). The bonding was performed under the following conditions.

Roller pressure: 0.27 MPa
Roller speed: 20 mm/sec
Table temperature: room temperature (RT)

After the bonding, the bonding state of the pressure-sensitive adhesive tape and the wafer was observed with a laser microscope (magnification: 100 times).

In addition, an image of the pressure-sensitive adhesive tape and the wafer was picked up from the pressure-sensitive adhesive tape side under a state in which the pressure-sensitive adhesive tape faced upward, and the image was binarized (8-bit grayscale, brightness: 0 to 255, threshold: 114) with image analysis software (Image J (free software)). After that, five bumps were randomly selected from the wafer, and the number of dots used for the display of one bump was counted. An image of only a bump in a state of having no tape bonded thereto has 220 dots. The fact that the number of dots measured under a state in which the pressure-sensitive adhesive tape was bonded to the wafer is closer to 220 indicates a more satisfactory embedding property. When a pressure-sensitive adhesive tape is bonded to a semiconductor wafer having a bump, the number of dots typically becomes about 820. An evaluation was performed by: marking a case in which the average number of dots for random five bumps was 700 or less with a double circle symbol (extremely satisfactory); marking a case in which the average number of dots was from 701 to 820 with a circle symbol (satisfactory); and marking a case in which the average number of dots was more than 820 with a triangle symbol (room for improvement).

### 7. Adhesive Residue

A silicon wafer was ground under the following conditions to produce a wafer having an exposed active surface.

Wafer used: 8-inch silicon mirror wafer
Backgrinder: DFG8560 (manufactured by DISCO Corporation)
Z1 wheel: spec: “GF01-SD360-VS-100”, size: “300×4Wx 4T”
Z2 wheel: spec: “BGT-270 IF-01-1-4/6-B-K09”, size: “300×5Tx3W”
Thickness after grinding: 500 μm
Grinding water: pure water

Three sheets of pressure-sensitive adhesive tapes (product name: “BT-315”) manufactured by Nitto Denko Corporation were superimposed on the produced wafer to produce a step. After that, the tapes were bonded to each other with a tape-bonding apparatus (manufactured by Nitto Seiki Co., Ltd., product name: “DR-3000III”) so that the step was transversed. Next, the resultant was warmed at 60° C. for 24 hours. After the warming, a UV irradiation machine (manufactured by Nitto Seiki Co., Ltd., product name: “UM-810”) was used to perform irradiation from a base material surface side with a high-pressure mercury lamp at 1, 000 mJ/cm². After the irradiation, the tape was peeled with a tensile tester at a peel angle of 180° and a peel rate of 300 mm/min, and an adhesive residue was visually observed with an optical microscope.

Conditions for the bonding are as described below.
Pressure: 0.4 MPa
Speed: 5 mm/sec
Table temperature: room temperature (RT)
Outer circumferential table height: 400 μm

An evaluation was performed by: marking a case in which almost no adhesive residue was visible on the surface of the wafer after the peeling of the pressure-sensitive adhesive tape with a double circle symbol (extremely satisfactory); marking a case in which an adhesive residue was linearly visible by observation with a microscope with a circle symbol (satisfactory); and marking a case in which an adhesive residue was observable even without use of a microscope with a triangle symbol (room for improvement).

The pressure-sensitive adhesive tapes in Examples of the present invention were each excellent in unevenness-embedding property for a surface of the semiconductor wafer having unevenness on a surface thereof. In addition, an adhesive residue was suppressed.

The pressure-sensitive adhesive tape for semiconductor wafer processing according to at least one embodiment of the present invention may be suitably used for an application of semiconductor wafer processing. The pressure-sensitive adhesive tape for semiconductor wafer processing may be suitably used as, for example, a backgrinding tape for semiconductor wafer processing.

According to at least one embodiment of the present invention, the pressure-sensitive adhesive tape for semiconductor wafer processing that is excellent in unevenness-embedding property, and is suppressed from creating adhesive residue on the surface of a semiconductor wafer can be provided.

What is claimed is:

1. A pressure-sensitive adhesive tape for semiconductor wafer processing, comprising:
a base material; and
a pressure-sensitive adhesive layer formed of an active energy ray-curable pressure-sensitive adhesive,
wherein a surface free energy X (mN/m) of the pressure-sensitive adhesive layer, and a quotient Y (I_{A}/T_{A}) between a tack value T_{A} (gf) and an integrated value I_{A} (gf·sec) of the pressure-sensitive adhesive layer measured by a probe tack method satisfy a relationship of:
$$Y > 0.01 X - 0.21 .$$

2. The pressure-sensitive adhesive tape according to claim 1,
wherein the active energy ray-curable pressure-sensitive adhesive contains a (meth) acrylic polymer, and
wherein the (meth) acrylic polymer is a polymer obtained by polymerization of a monomer composition containing 60 mol % or more of a (meth) acrylic monomer having a side chain having 8 or more carbon atoms.

3. The pressure-sensitive adhesive tape according to claim 2, wherein the monomer composition contains 39 mol % or less of at least one kind selected from the group consisting of: a monomer having a side chain having 2 or less carbon atoms; and a high-polarity monomer.

4. The pressure-sensitive adhesive tape according to claim 3, wherein the high-polarity monomer is a hydroxy group-containing monomer having a side chain having 4 or less carbon atoms.

5. The pressure-sensitive adhesive tape according to claim 4, wherein the monomer composition contains 10 mol % to 39 mol % of the hydroxy group-containing monomer having a side chain having 4 or less carbon atoms.

6. The pressure-sensitive adhesive tape according to claim 1, further comprising an intermediate layer.

7. The pressure-sensitive adhesive tape according to claim 1, wherein the pressure-sensitive adhesive tape is a backgrinding tape.

8. The pressure-sensitive adhesive tape according to claim 2, wherein the pressure-sensitive adhesive tape is a backgrinding tape.

9. The pressure-sensitive adhesive tape according to claim 3, wherein the pressure-sensitive adhesive tape is a backgrinding tape.

10. The pressure-sensitive adhesive tape according to claim 4, wherein the pressure-sensitive adhesive tape is a backgrinding tape.

11. The pressure-sensitive adhesive tape according to claim 5, wherein the pressure-sensitive adhesive tape is a backgrinding tape.

12. The pressure-sensitive adhesive tape according to claim 6, wherein the pressure-sensitive adhesive tape is a backgrinding tape.
